(19) United States
(12) Patent Application Publication
(10) Pub. No.: US 2025/0359126 A1
(43) Pub. Date: Nov. 20, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Takuma NANJO, Tokyo (JP); Tatsuro WATAHIKI, Tokyo (JP)

(73) Assignee: Mitsubishi Electric Corporation, Tokyo (JP)

(21) Appl. No.: 18/868,177

(22) PCT Filed: Mar. 20, 2023
(86) PCT No.: PCT/JP2023/010900

§ 371 Date: Nov. 22, 2024

(30) Foreign Application Priority Data
May 30, 2022 (JP) 2022-087382

(51) Int. Cl. H10D 30/47; H10D 30/01; H10D 62/10; H10D 62/824; H10D 64/27; H10D 64/62

(52) U.S. Cl. CPC H10D 30/475; H10D 30/015; H10D 62/102; H10D 62/824; H10D 64/411; H10D 64/62

(57) ABSTRACT

The present disclosure relates to a semiconductor device, and the semiconductor device includes: a semiconductor substrate; a channel layer provided over the semiconductor substrate and formed of a first nitride semiconductor; a barrier layer provided over the channel layer and formed of a second nitride semiconductor having a larger band gap than the first nitride semiconductor; a metal film selectively formed above the barrier layer; a composite layer provided to be in contact with the metal film and having at least a conductive material and an insulating material; and an insulating film formed over the barrier layer in a region where the metal film and the composite layer are not formed.

### TECHNICAL FIELD

The present disclosure relates to semiconductor devices and, in particular, to heterojunction field effect semiconductor devices formed of a semiconductor including nitride.

### BACKGROUND ART

One example of a conventional heterojunction field effect semiconductor device formed of a semiconductor including nitride (a nitride semiconductor) includes a heterojunction field effect transistor disclosed in Patent Document 1, for example. The heterojunction field effect transistor has an AlGaN/GaN heterojunction including a channel layer of GaN (gallium nitride) and a barrier layer of AlGaN (aluminum gallium nitride).

Ohmic electrodes formed of a metal film of Ti (titanium), Al (aluminum), Mo (molybdenum), and the like or a metal multilayer film or an alloy film including them are provided over the barrier layer to form a drain electrode and a source electrode of the transistor.

These ohmic electrodes are covered with an insulating film formed of SiN (silicon nitride) or SiO₂ (silicon oxide) and are connected to wiring for external connection via contact holes formed by opening the insulating film to expose portions of upper surfaces of the ohmic electrodes.

An ohmic electrode is generally formed, after deposition of a metal film (including a metal multilayer film and an alloy film) over a semiconductor layer, by heat treating the metal film and then depositing an SiN film to cover the heat treated metal film.

### PRIOR ART DOCUMENTS

### Patent Document

Patent Document 1: Japanese Patent Application Laid-Open No. 2014-179389

### SUMMARY

### Problem to be Solved by the Invention

It is desired that ohmic electrodes, such as a source electrode, a drain electrode, and a cathode electrode, for use in a semiconductor device, such as a transistor and a diode, formed over a semiconductor layer having an AlGaN/GaN heterojunction have the lowest possible resistance to improve performance of the semiconductor device.

An ohmic electrode is generally formed by performing heat treatment at a high temperature of more than 600° C. after deposition of a metal film over the semiconductor layer and alloying the metal film with the semiconductor layer to reduce resistance. A surface protective film of SiN and the like is then formed to protect the surface of the semiconductor layer, and, at the same time, the metal film is covered. When heat treatment at a high temperature is performed with the metal film being exposed as described above, however, a portion of the metal film evaporates and adheres again to a region other than a region where the electrode is formed and remains between the semiconductor layer and the protective film to negatively affect various characteristics of the semiconductor device in some cases.

On the other hand, heat treatment at a high temperature is sometimes performed with a cap film of SiN and the like having a low reactivity with the metal film being deposited to cover the metal film to prevent evaporation and re-adherence of metal, and then the cap film is removed, but this complicates a manufacturing process and increases a manufacturing cost in some cases as a process of depositing the cap film and then removing the cap film is added.

The present disclosure has been conceived to solve problems as described above, and it is an object of the present disclosure to provide a semiconductor device allowing for suppression of complication of a manufacturing process without reducing characteristics as the semiconductor device.

### Means to Solve the Problem

A semiconductor device according to the present disclosure includes: a semiconductor substrate; a channel layer provided over the semiconductor substrate and formed of a first nitride semiconductor; a barrier layer provided over the channel layer and formed of a second nitride semiconductor having a larger band gap than the first nitride semiconductor; a metal film selectively formed above the barrier layer; a composite layer provided to be in contact with the metal film and having at least a conductive material and an insulating material; and an insulating film formed over the barrier layer in a region where the metal film and the composite layer are not formed.

### Effects of the Invention

According to the semiconductor device according to the present disclosure, a semiconductor device allowing for suppression of complication of a manufacturing process without reducing characteristics as the semiconductor device can be obtained.

### BRIEF DESCRIPTION OF DRAWINGS

FIG. 1 is a cross-sectional view illustrating a configuration of a semiconductor device according to Embodiment 1 according to the present disclosure.

FIG. 2 is a diagram schematically showing a flow of a current through the semiconductor device according to Embodiment 1 according to the present disclosure.

FIG. 3 is a cross-sectional view illustrating a method of manufacturing the semiconductor device according to Embodiment 1 according to the present disclosure.

FIG. 4 is a cross-sectional view illustrating the method of manufacturing the semiconductor device according to Embodiment 1 according to the present disclosure.

FIG. 5 is a cross-sectional view illustrating the method of manufacturing the semiconductor device according to Embodiment 1 according to the present disclosure.

FIG. 6 is a cross-sectional view illustrating the method of manufacturing the semiconductor device according to Embodiment 1 according to the present disclosure.

FIG. 7 is a cross-sectional view illustrating the method of manufacturing the semiconductor device according to Embodiment 1 according to the present disclosure.

FIG. 8 is a cross-sectional view illustrating a configuration of a semiconductor device according to Embodiment 2 according to the present disclosure.

FIG. 9 is a cross-sectional view illustrating a method of manufacturing the semiconductor device according to Embodiment 2 according to the present disclosure.

FIG. 10 is a cross-sectional view illustrating a configuration of a semiconductor device according to Embodiment 3 according to the present disclosure.

FIG. 11 is a cross-sectional view illustrating a method of manufacturing the semiconductor device according to Embodiment 3 according to the present disclosure.

FIG. 12 is a cross-sectional view illustrating the method of manufacturing the semiconductor device according to Embodiment 3 according to the present disclosure.

FIG. 13 is a cross-sectional view illustrating the method of manufacturing the semiconductor device according to Embodiment 3 according to the present disclosure.

FIG. 14 is a cross-sectional view illustrating the method of manufacturing the semiconductor device according to Embodiment 3 according to the present disclosure.

FIG. 15 is a cross-sectional view illustrating the method of manufacturing the semiconductor device according to Embodiment 3 according to the present disclosure.

FIG. 16 is a cross-sectional view illustrating the method of manufacturing the semiconductor device according to Embodiment 3 according to the present disclosure.

FIG. 17 is a cross-sectional view illustrating a configuration of a semiconductor device according to Embodiment 4 according to the present disclosure.

FIG. 18 is a cross-sectional view illustrating a method of manufacturing the semiconductor device according to Embodiment 4 according to the present disclosure.

FIG. 19 is a cross-sectional view illustrating a configuration of a semiconductor device according to Embodiment 5 according to the present disclosure.

FIG. 20 is a cross-sectional view illustrating a method of manufacturing the semiconductor device according to Embodiment 5 according to the present disclosure.

FIG. 21 is a cross-sectional view illustrating the method of manufacturing the semiconductor device according to Embodiment 5 according to the present disclosure.

FIG. 22 is a cross-sectional view illustrating the method of manufacturing the semiconductor device according to Embodiment 5 according to the present disclosure.

FIG. 23 is a cross-sectional view illustrating the method of manufacturing the semiconductor device according to Embodiment 5 according to the present disclosure.

FIG. 24 is a cross-sectional view illustrating the method of manufacturing the semiconductor device according to Embodiment 5 according to the present disclosure.

FIG. 25 is a cross-sectional view illustrating the method of manufacturing the semiconductor device according to Embodiment 5 according to the present disclosure.

FIG. 26 is a cross-sectional view illustrating the method of manufacturing the semiconductor device according to Embodiment 5 according to the present disclosure.

FIG. 27 is a cross-sectional view illustrating a configuration of a semiconductor device according to Embodiment 6 according to the present disclosure.

FIG. 28 is a cross-sectional view illustrating a method of manufacturing the semiconductor device according to Embodiment 6 according to the present disclosure.

FIG. 29 is a cross-sectional view illustrating a semiconductor device according to Embodiment 7 according to the present disclosure with a metal film and an insulating film not being formed.

FIG. 30 is a cross-sectional view schematically showing a 2DEG induced at an AlGaN/GaN interface of the semiconductor device according to Embodiment 7 according to the present disclosure.

FIG. 31 is a cross-sectional view illustrating a configuration of a semiconductor device according to Embodiment 9 according to the present disclosure.

FIG. 32 is a cross-sectional view illustrating a configuration of a semiconductor device according to Embodiment 10 according to the present disclosure.

FIG. 33 is a cross-sectional view illustrating a configuration of a semiconductor device according to Embodiment 11 according to the present disclosure.

FIG. 34 is a cross-sectional view illustrating a configuration of a semiconductor device according to Embodiment 12 according to the present disclosure.

### DESCRIPTION OF EMBODIMENTS

### Embodiment 1

### <Device Configuration>

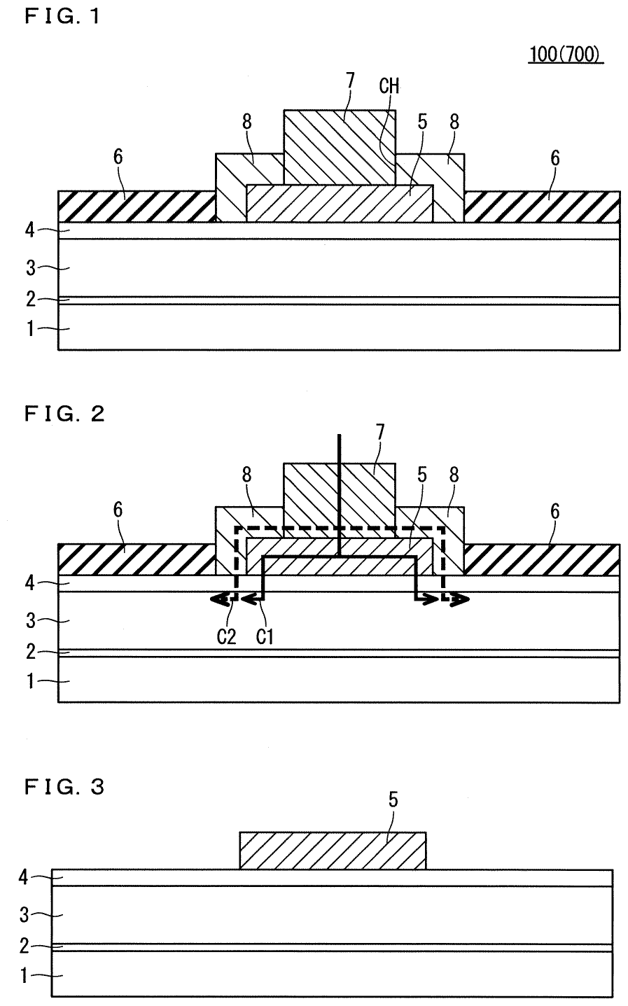

FIG. 1 is a cross-sectional view illustrating a configuration of a semiconductor device 100 according to Embodiment 1 according to the present disclosure. Only a main electrode portion as a portion of a heterojunction field effect transistor is illustrated in FIG. 1 for the sake of convenience, for example.

As illustrated in FIG. 1, in the semiconductor device 100, a channel layer 3 formed of GaN (a first nitride semiconductor) is stacked over a semiconductor substrate 1 formed of silicon carbide (SiC), for example, via a buffer layer 2 formed of AlN (aluminum nitride), and a barrier layer 4 formed of AlGaN (a second nitride semiconductor) and forming a heterojunction with the channel layer 3 is formed over the channel layer 3. By using such nitride semiconductors, a practical heterojunction field effect transistor can be obtained. Assume that AlGaN forming the barrier layer 4 has a larger band gap than GaN forming the channel layer 3.

A metal film 5 forming a drain electrode, a source electrode, and the like is selectively provided over the barrier layer 4, and a side surface and a portion of an upper surface of the metal film 5 are covered with a composite layer 8 of metal and an insulator. An insulating film 6 of SiO₂, SiN, or the like is provided over the barrier layer 4 in a region other than a region where the composite layer 8 and the metal film 5 are formed.

A portion of the composite layer 8 over the upper surface of the metal film 5 has a contact hole CH from which a portion of the upper surface of the metal film 5 is exposed, and a wiring layer 7 is provided to be in contact with the metal film 5 via the contact hole CH.

The composite layer 8 is a silicide layer resulting from reaction of the metal film 5 and SiO₂ or a silicide layer resulting from reaction of the metal film 5 and SiN, for example, and includes a conductive portion having a lower resistance than the metal film 5. The composite layer 8 is not limited to the silicide layer, and any layer having conductivity resulting from composition of a conductive material and an insulating material due to heat treatment at a temperature of 600° C. or more can be used, for example.

FIG. 2 is a diagram schematically showing a current flowing to the channel layer 3 via the wiring layer 7. As illustrated in FIG. 2, the current flows to the channel layer 3 via the wiring layer 7 through two types of paths, that is, a current path C1 through which the current flows from the wiring layer 7 to the channel layer 3 via the metal film 5 and a current path C2 through which the current flows from the wiring layer 7 to the channel layer 3 via the composite layer 8, so that an effect of reducing a contact resistance is obtained.

One example of the contact resistance is herein a contact resistance of 0.6 Ωmm to 0.7 Ωmm when the insulating film 6 is formed of SiO₂, and the barrier layer 4 of AlGaN has an Al composition of 26% and a thickness of 15 nm. It is predicted that the contact resistance increases when the barrier layer 4 has a smaller Al composition and a smaller thickness than the above-mentioned numerical values.

Such a structure in which the metal film 5 is covered with the composite layer 8 can be obtained by forming the metal film 5 over the barrier layer 4, depositing the insulating film 6 to cover the barrier layer 4 and the metal film 5, and then performing heat treatment at a high temperature of 600° C. or more, for example, to alloy the metal film 5 with the barrier layer 4 to form an ohmic electrode and to react the metal film 5 and the insulating film 6 to form a silicide layer. In this case, the insulating film 6 over the barrier layer 4 functions as a protective film to protect the barrier layer 4 and the semiconductor layers below the barrier layer 4 and can prevent evaporation of metal and re-adherence of metal to the barrier layer 4 during heat treatment at a high temperature without adding a new process.

### <Manufacturing Method>

A method of manufacturing the semiconductor device 100 will be described next with reference to FIGS. 3 to 7 sequentially illustrating manufacturing steps. In FIGS. 3 to 7, the same components as those of the semiconductor device 100 illustrated in FIG. 1 bear the same reference signs as those of the same components, and redundant description is omitted.

First, in a step illustrated in FIG. 3, the buffer layer 2 formed of AlN, the channel layer 3 formed of GaN, and the barrier layer 4 formed of AlGaN are grown over the semiconductor substrate 1 of SiC in this order by epitaxial growth, such as metal organic chemical vapor deposition (MOCVD) and molecular beam epitaxy (MBE). Next, the metal film 5 is formed in a desired region using vapor deposition and lift-off. The metal film 5 can be a single layer film of Ti, Al, Ni (nickel), Au (gold), Mo, and the like or a multilayer film of them.

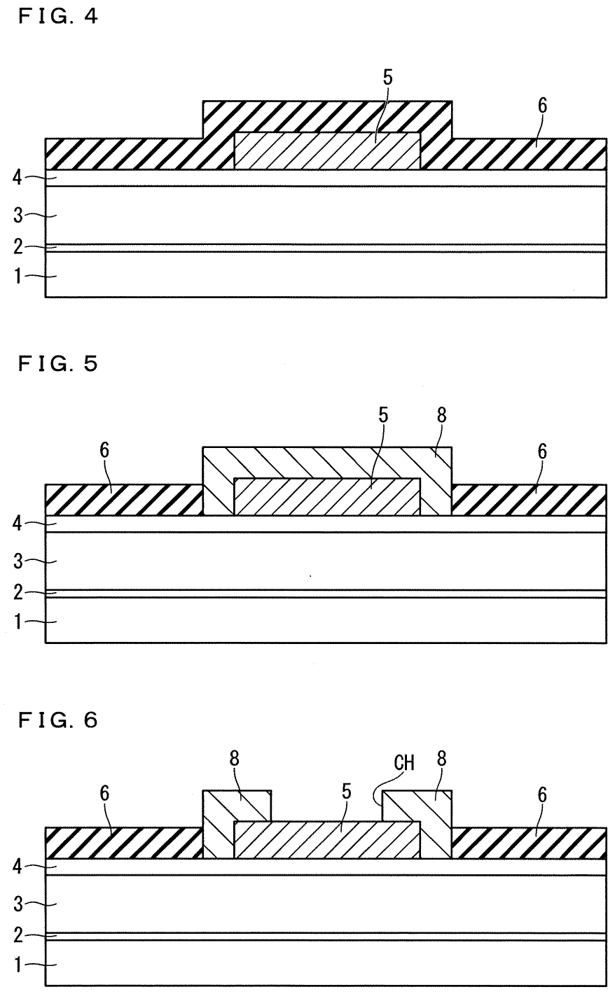

Next, in a step illustrated in FIG. 4, the insulating film 6 is deposited over the barrier layer 4 to cover the metal film 5, for example, by plasma CVD. As the insulating film 6, SiO₂ or SiN can be formed, for example. A method of forming the insulating film 6 is not limited to plasma CVD, and thermal CVD and sputtering can be used.

Next, in a step illustrated in FIG. 5, heat treatment is performed at a temperature of 500° C. to 900° C., more preferably, at a temperature of 800° C. to 850° C. by rapid thermal annealing (RTA) and the like to react a portion where the metal film 5 and the insulating film 6 are in contact with each other to form a silicide layer to be the composite layer 8, and the metal film 5 is covered with the composite layer 8 and is alloyed with the barrier layer 4 to form an ohmic electrode.

Next, in a step illustrated in FIG. 6, the composite layer 8 in a region where the wiring layer 7 is formed is removed by dry etching, for example, using a resist material as a mask to form the contact hole CH having a bottom surface from which the upper surface of the metal film 5 is exposed.

Next, in a step illustrated in FIG. 7, a resist mask RM having an opening OP in a portion where the wiring layer 7 is desired to be formed is formed over the composite layer 8 and the insulating film 6. Then, a single layer film of Ti, Al, Ni, Au, and the like or a multilayer film of them is formed on the resist mask RM and in the opening OP by vapor deposition, and the resist mask RM is removed by lift-off to form the wiring layer 7, so that the semiconductor device 100 illustrated in FIG. 1 is obtained.

### Embodiment 2

### <Device Configuration>

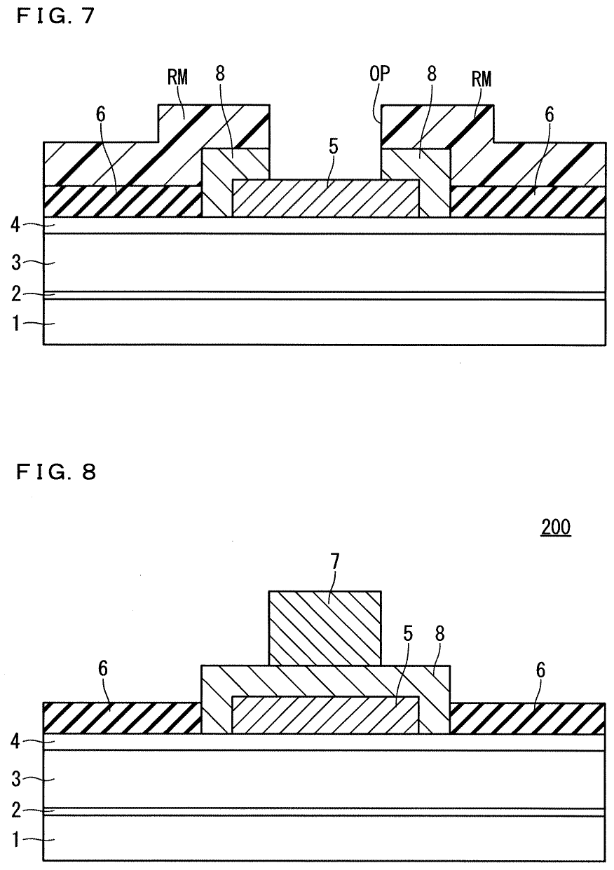

FIG. 8 is a cross-sectional view illustrating a configuration of a semiconductor device 200 according to Embodiment 2 according to the present disclosure. In FIG. 8, the same components as those of the semiconductor device 100 described with reference to FIG. 1 bear the same reference signs as those of the same components, and redundant description is omitted.

As illustrated in FIG. 8, in the semiconductor device 200, the metal film 5 is covered with the composite layer 8, and the insulating film 6 of SiO₂, SiN, or the like is provided in a region over the barrier layer 4 other than a region where the composite layer 8 and the metal film 5 are formed.

The wiring layer 7 is selectively provided over an upper surface of the composite layer 8. The composite layer 8 is the silicide layer resulting from reaction of the metal film 5 and SiO₂ or the silicide layer resulting from reaction of the metal film 5 and SiN, for example, and includes the conductive portion having a lower resistance than the metal film 5. The current thus flows to the channel layer 3 via the wiring layer 7 through two types of paths, that is, a current path through which the current flows from the wiring layer 7 to the channel layer 3 via the composite layer 8 and the metal film 5 and a current path through which the current flows from the wiring layer 7 to the channel layer 3 via the composite layer 8, so that the effect of reducing the contact resistance is obtained.

The insulating film 6 over the barrier layer 4 provided to obtain such a structure in which the metal film 5 is covered with the composite layer 8 functions as the protective film to protect the barrier layer 4 and the semiconductor layers below the barrier layer 4 during heat treatment and can prevent evaporation of metal and re-adherence of metal to the barrier layer 4 during heat treatment at a high temperature without adding a new process.

Furthermore, the wiring layer 7 is provided to be in contact with the upper surface of the composite layer 8 to eliminate the need to provide the contact hole in the composite layer 8, so that manufacturing steps can be simplified.

### <Manufacturing Method>

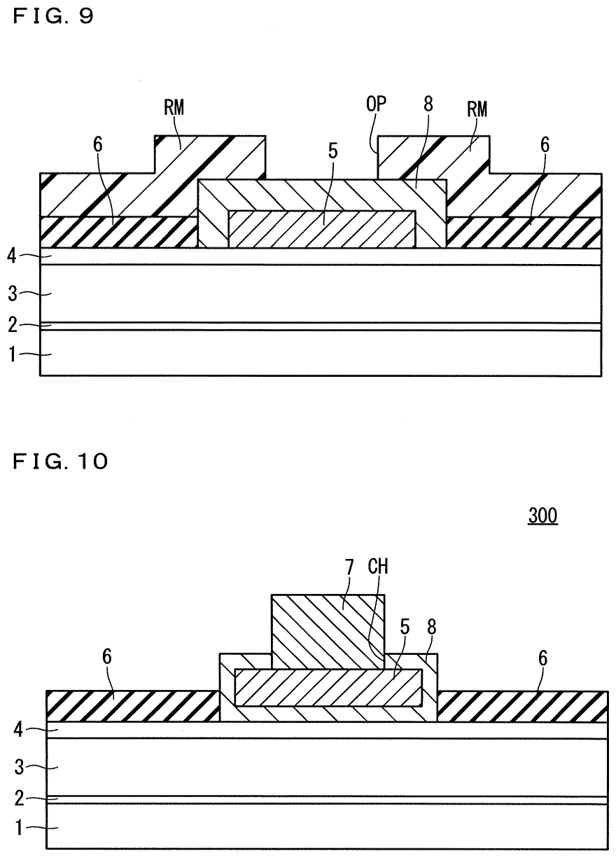

A method of manufacturing the semiconductor device 200 will be described next with reference to FIG. 9 illustrating a manufacturing step. Steps before the step illustrated in FIG. 9 are the same as the steps illustrated in FIGS. 3 to 5 with reference to which the method of manufacturing the semiconductor device 100 according to Embodiment 1 has been described, and the portion where the metal film 5 and the insulating film 6 are in contact with each other is reacted by RTA and the like to form the silicide layer to be the composite layer 8, and the metal film 5 is covered with the composite layer 8 and is alloyed with the barrier layer 4 to form the ohmic electrode.

Then, in the step illustrated in FIG. 9, the resist mask RM having the opening OP in the portion where the wiring layer 7 is desired to be formed is formed over the composite layer 8 and the insulating film 6. Then, the single layer film of Ti, Al, Ni, Au, and the like or the multilayer film of them is formed on the resist mask RM and in the opening OP by vapor deposition, and the resist mask RM is removed by lift-off to form the wiring layer 7, so that the semiconductor device 200 illustrated in FIG. 8 is obtained.

### Embodiment 3

### <Device Configuration>

FIG. 10 is a cross-sectional view illustrating a configuration of a semiconductor device 300 according to Embodiment 3 according to the present disclosure. In FIG. 10, the same components as those of the semiconductor device 100 described with reference to FIG. 1 bear the same reference signs as those of the same components, and redundant description is omitted.

As illustrated in FIG. 10, in the semiconductor device 300, the upper surface and the side surface of the metal film 5 are covered with the composite layer 8, the composite layer 8 is provided also between a lower surface of the metal film 5 and the barrier layer 4, and the insulating film 6 of SiO₂, SiN, or the like is provided in the region over the barrier layer 4 other than the region where the composite layer 8 and the metal film 5 are formed.

The portion of the composite layer 8 over the upper surface of the metal film 5 has the contact hole CH from which the portion of the upper surface of the metal film 5 is exposed, and the wiring layer 7 is provided to be in contact with the metal film 5 via the contact hole CH.

The composite layer 8 is the silicide layer resulting from reaction of the metal film 5 and SiO₂ or the silicide layer resulting from reaction of the metal film 5 and SiN, for example, and includes the conductive portion having a lower resistance than the metal film 5. The current thus flows to the channel layer 3 via the wiring layer 7 through two types of paths, that is, a current path through which the current flows from the wiring layer 7 to the channel layer 3 via the metal film 5 and a lower composite layer 8 and a current path through which the current flows from the wiring layer 7 to the channel layer 3 via the composite layer 8, so that the effect of reducing the contact resistance is obtained. Due to a structure in which the lower composite layer 8 and the barrier layer 4 are in contact with each other, the contact resistance can further be reduced compared with the semiconductor device 100 according to Embodiment 1.

The insulating film 6 over the barrier layer 4 provided to obtain such a structure in which the metal film 5 is covered with the composite layer 8 functions as the protective film to protect the barrier layer 4 and the semiconductor layers below the barrier layer 4 during heat treatment and can prevent evaporation of metal and re-adherence of metal to the barrier layer 4 during heat treatment at a high temperature without adding a new process.

### <Manufacturing Method>

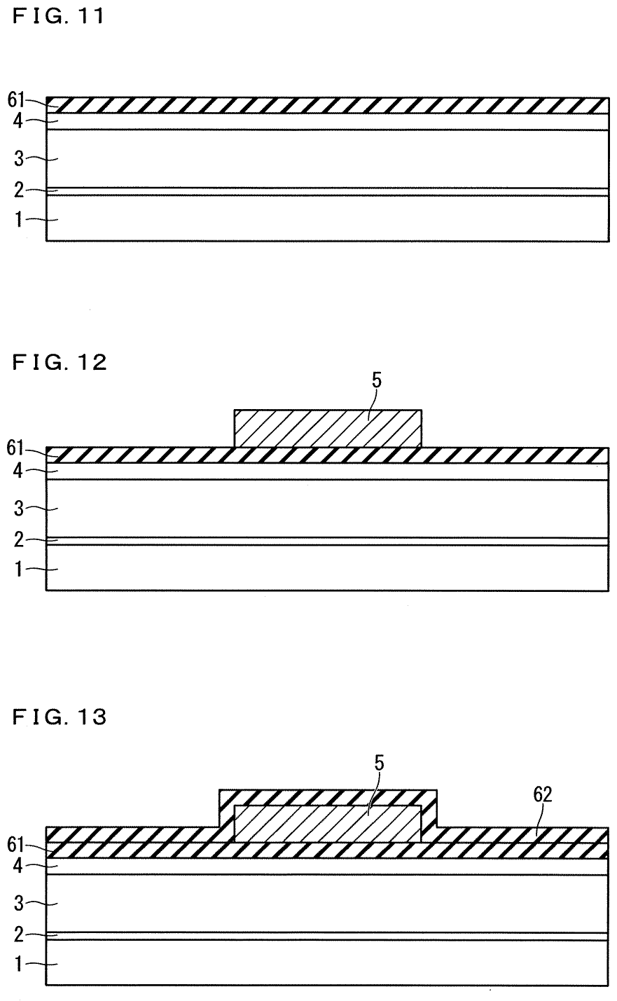

A method of manufacturing the semiconductor device 300 will be described next with reference to FIGS. 11 to 16 sequentially illustrating manufacturing steps.

First, in a step illustrated in FIG. 11, the buffer layer 2 formed of AlN, the channel layer 3 formed of GaN, and the barrier layer 4 formed of AlGaN are grown over the semiconductor substrate 1 of SiC in this order by epitaxial growth, such as MOCVD and MBE. Next, an insulating film 61 (a first insulating film) is deposited over the barrier layer 4, for example, by plasma CVD. As the insulating film 61, SiO₂ or SiN can be formed, for example.

Next, in a step illustrated in FIG. 12, the metal film 5 is formed in a desired region over the insulating film 61 using vapor deposition and lift-off. The metal film 5 can be a single layer film of Ti, Al, Ni, Au, Mo, and the like or a multilayer film of them.

Next, in a step illustrated in FIG. 13, an insulating film 62 (a second insulating film) is deposited to cover the metal film 5 and the insulating film 61, for example, by plasma CVD. As the insulating film 62, SiO₂ or SiN can be formed as with the insulating film 61. A method of forming the insulating films 61 and 62 is not limited to plasma CVD, and thermal CVD and sputtering can be used.

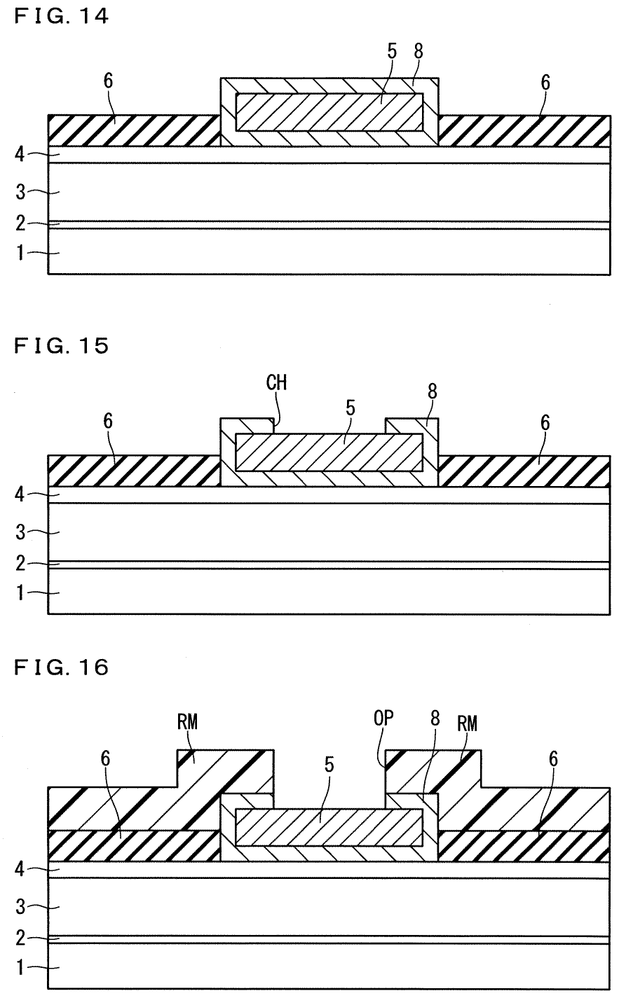

Next, in a step illustrated in FIG. 14, heat treatment is performed at a temperature of 500° C. to 900° C. by RTA and the like to react the portion where the metal film 5 and the insulating film 6 are in contact with each other to form the silicide layer to be the composite layer 8, the metal film 5 as a whole is covered with the composite layer 8, and the metal film 5, the composite layer 8, and the barrier layer 4 are mutually alloyed to form the ohmic electrode. In FIG. 14, the insulating films 61 and 62 are integrally represented as the insulating film 6.

Next, in a step illustrated in FIG. 15, the composite layer 8 in the region where the wiring layer 7 is formed is removed by dry etching, for example, using the resist material as the mask to form the contact hole CH having the bottom surface from which the upper surface of the metal film 5 is exposed.

Next, in a step illustrated in FIG. 16, the resist mask RM having the opening OP in the portion where the wiring layer 7 is desired to be formed is formed over the composite layer 8 and the insulating film 6. Then, the single layer film of Ti, Al, Ni, Au, and the like or the multilayer film of them is formed on the resist mask RM and in the opening OP by vapor deposition, and the resist mask RM is removed by lift-off to form the wiring layer 7, so that the semiconductor device 300 illustrated in FIG. 10 is obtained.

### Embodiment 4

### <Device Configuration>

FIG. 17 is a cross-sectional view illustrating a configuration of a semiconductor device 400 according to Embodiment 4 according to the present disclosure. In FIG. 17, the same components as those of the semiconductor device 100 described with reference to FIG. 1 bear the same reference signs as those of the same components, and redundant description is omitted.

As illustrated in FIG. 17, in the semiconductor device 400, the upper surface and the side surface of the metal film 5 are covered with the composite layer 8, the composite layer 8 is provided also between the lower surface of the metal film 5 and the barrier layer 4, and the insulating film 6 of SiO₂, SiN, or the like is provided in the region over the barrier layer 4 other than the region where the composite layer 8 and the metal film 5 are formed.

The wiring layer 7 is selectively provided over the upper surface of the composite layer 8. The composite layer 8 is the silicide layer resulting from reaction of the metal film 5 and SiO₂ or the silicide layer resulting from reaction of the metal film 5 and SiN, for example, and includes the conductive portion having a lower resistance than the metal film 5. The current thus flows to the channel layer 3 via the wiring layer 7 through two types of paths, that is, a current path through which the current flows from the wiring layer 7 to the channel layer 3 via an upper composite layer 8, the metal film 5, and the lower composite layer 8 and the current path through which the current flows from the wiring layer 7 to the channel layer 3 via the composite layer 8, so that the effect of reducing the contact resistance is obtained.

The insulating film 6 over the barrier layer 4 provided to obtain such a structure in which the metal film 5 is covered with the composite layer 8 functions as the protective film to protect the barrier layer 4 and the semiconductor layers below the barrier layer 4 during heat treatment and can prevent evaporation of metal and re-adherence of metal to the barrier layer 4 during heat treatment at a high temperature without adding a new process.

Furthermore, the wiring layer 7 is provided to be in contact with the upper surface of the composite layer 8 to eliminate the need to provide the contact hole in the composite layer 8, so that the manufacturing step can be simplified.

### <Manufacturing Method>

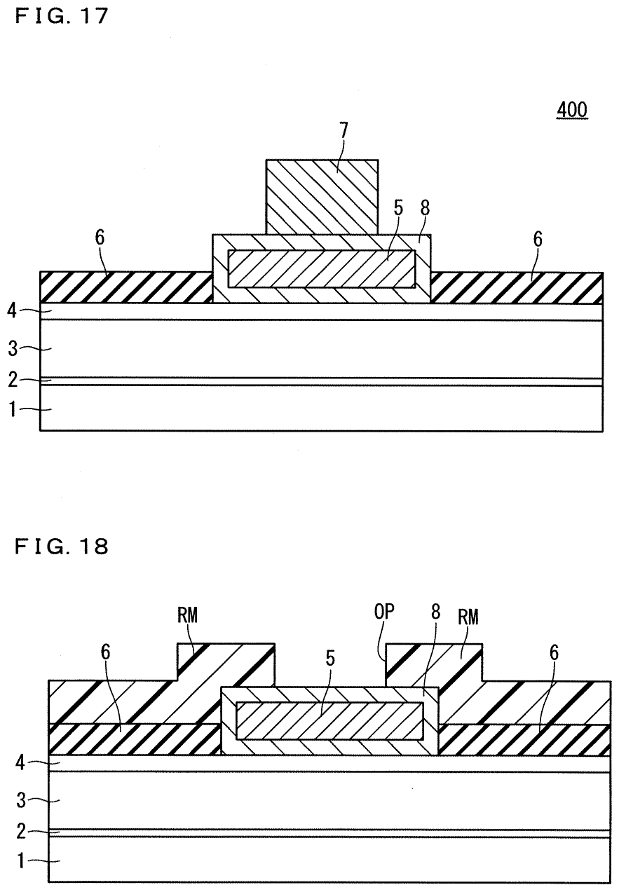

A method of manufacturing the semiconductor device 400 will be described next with reference to FIG. 18 illustrating a manufacturing step. Steps before the step illustrated in FIG. 18 are the same as the steps illustrated in FIGS. 11 to 14 with reference to which the method of manufacturing the semiconductor device 300 according to Embodiment 3 has been described, and the portion where the metal film 5 and the insulating film 6 are in contact with each other is reacted by RTA and the like to form the silicide layer to be the composite layer 8, the metal film 5 as a whole is covered with the composite layer 8, and the metal film 5, the composite layer 8, and the barrier layer 4 are mutually alloyed to form the ohmic electrode.

Then, in the step illustrated in FIG. 18, the resist mask RM having the opening OP in the portion where the wiring layer 7 is desired to be formed is formed over the composite layer 8 and the insulating film 6. Then, the single layer film of Ti, Al, Ni, Au, and the like or the multilayer film of them is formed on the resist mask RM and in the opening OP by vapor deposition, and the resist mask RM is removed by lift-off to form the wiring layer 7, so that the semiconductor device 400 illustrated in FIG. 17 is obtained.

### Embodiment 5

### <Device Configuration>

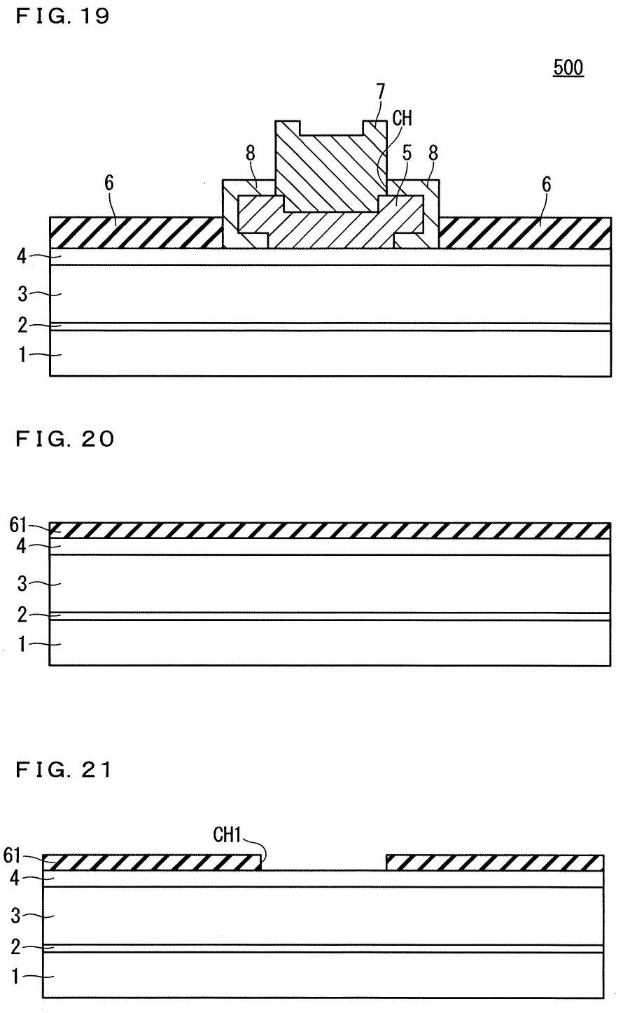

FIG. 19 is a cross-sectional view illustrating a configuration of a semiconductor device 500 according to Embodiment 5 according to the present disclosure. In FIG. 19, the same components as those of the semiconductor device 100 described with reference to FIG. 1 bear the same reference signs as those of the same components, and redundant description is omitted.

As illustrated in FIG. 19, in the semiconductor device 500, the upper surface and the side surface of the metal film 5 are covered with the composite layer 8, the composite layer 8 is provided also between a portion of the lower surface of the metal film 5 and the barrier layer 4, and the insulating film 6 of SiO₂, SiN, or the like is provided in the region over the barrier layer 4 other than the region where the composite layer 8 and the metal film 5 are formed.

The portion of the composite layer 8 over the upper surface of the metal film 5 has the contact hole CH from which the portion of the upper surface of the metal film 5 is exposed, and the wiring layer 7 is provided to be in contact with the metal film 5 via the contact hole CH.

The composite layer 8 is the silicide layer resulting from reaction of the metal film 5 and SiO₂ or the silicide layer resulting from reaction of the metal film 5 and SiN, for example, and includes the conductive portion having a lower resistance than the metal film 5. The current thus flows to the channel layer 3 via the wiring layer 7 through two types of paths, that is, the current path through which the current flows from the wiring layer 7 to the channel layer 3 via the metal film 5 and the current path through which the current flows from the wiring layer 7 to the channel layer 3 via the composite layer 8, so that the effect of reducing the contact resistance is obtained. Due to a structure in which the metal film 5 and the barrier layer 4 are in contact with each other, the metal film 5 is alloyed with the barrier layer 4 to form the ohmic electrode by performing heat treatment at a high temperature of 600° C. or more, for example, for formation of the composite layer 8, so that the contact resistance can further be reduced.

In this case, the insulating film 6 over the barrier layer 4 functions as the protective film to protect the barrier layer 4 and the semiconductor layers below the barrier layer 4 and can prevent evaporation of metal and re-adherence of metal to the barrier layer 4 during heat treatment at a high temperature without adding a new process.

### <Manufacturing Method>

A method of manufacturing the semiconductor device 500 will be described next with reference to FIGS. 20 to 26 sequentially illustrating manufacturing steps.

First, in a step illustrated in FIG. 20, the buffer layer 2 formed of AlN, the channel layer 3 formed of GaN, and the barrier layer 4 formed of AlGaN are grown over the semiconductor substrate 1 of SiC in this order by epitaxial growth, such as MOCVD and MBE. Next, the insulating film 61 is deposited over the barrier layer 4, for example, by plasma CVD. As the insulating film 61, SiO₂ or SiN can be formed, for example.

Next, in a step illustrated in FIG. 21, the insulating film 61 in a region where the metal film 5 is formed is removed by dry etching, for example, using a resist material as a mask to form a contact hole CHI having a bottom surface from which an upper surface of the barrier layer 4 is exposed.

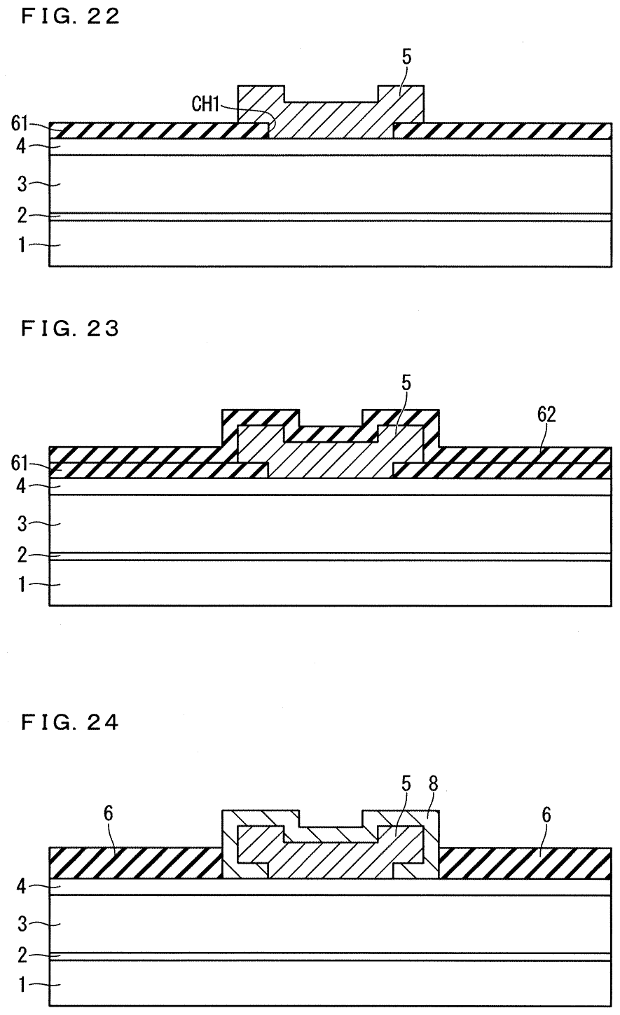

Next, in a step illustrated in FIG. 22, the metal film 5 is formed in a desired region over the insulating film 61 including a region over the contact hole CHI using vapor deposition and lift-off. The metal film 5 can be a single layer film of Ti, Al, Ni, Au, Mo, and the like or a multilayer film of them.

Next, in a step illustrated in FIG. 23, the insulating film 62 is deposited to cover the metal film 5 and the insulating film 61, for example, by plasma CVD. As the insulating film 62, SiO₂ or SiN can be formed as with the insulating film 61. The method of forming the insulating films 61 and 62 is not limited to plasma CVD, and thermal CVD and sputtering can be used.

Next, in a step illustrated in FIG. 24, heat treatment is performed at a temperature of 500° C. to 900° C. by RTA and the like to react the portion where the metal film 5 and the insulating film 6 are in contact with each other to form the silicide layer to be the composite layer 8, the metal film 5 is covered with the composite layer 8, and the metal film 5, the composite layer 8, and the barrier layer 4 are mutually alloyed to form the ohmic electrode. In this case, the composite layer 8 is formed also between the portion of the lower surface of the metal film 5 and the barrier layer 4. In FIG. 24, the insulating films 61 and 62 are integrally represented as the insulating film 6.

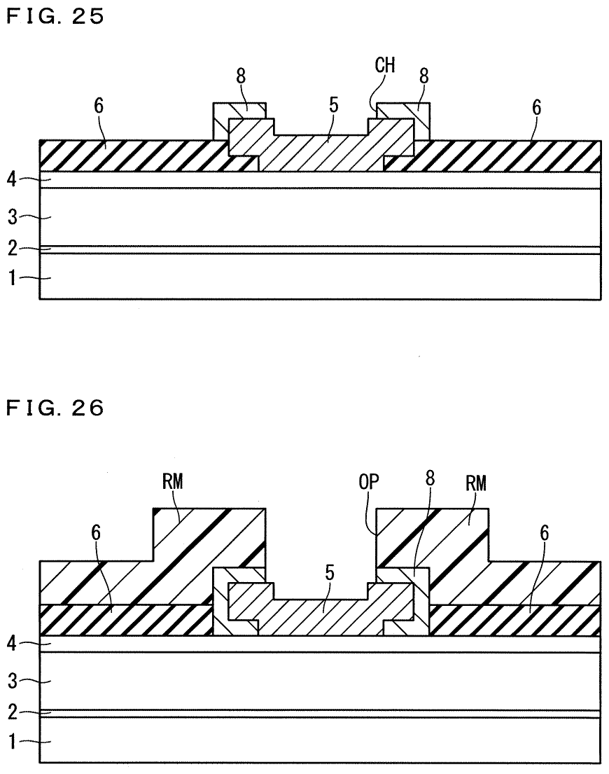

Next, in a step illustrated in FIG. 25, the composite layer 8 in the region where the wiring layer 7 is formed is removed by dry etching, for example, using the resist material as the mask to form the contact hole CH having the bottom surface from which the upper surface of the metal film 5 is exposed.

Next, in a step illustrated in FIG. 26, the resist mask RM having the opening OP in the portion where the wiring layer 7 is desired to be formed is formed over the composite layer 8 and the insulating film 6. Then, the single layer film of Ti, Al, Ni, Au, and the like or the multilayer film of them is formed on the resist mask RM and in the opening OP by vapor deposition, and the resist mask RM is removed by lift-off to form the wiring layer 7, so that the semiconductor device 500 illustrated in FIG. 19 is obtained.

### Embodiment 6

### <Device Configuration>

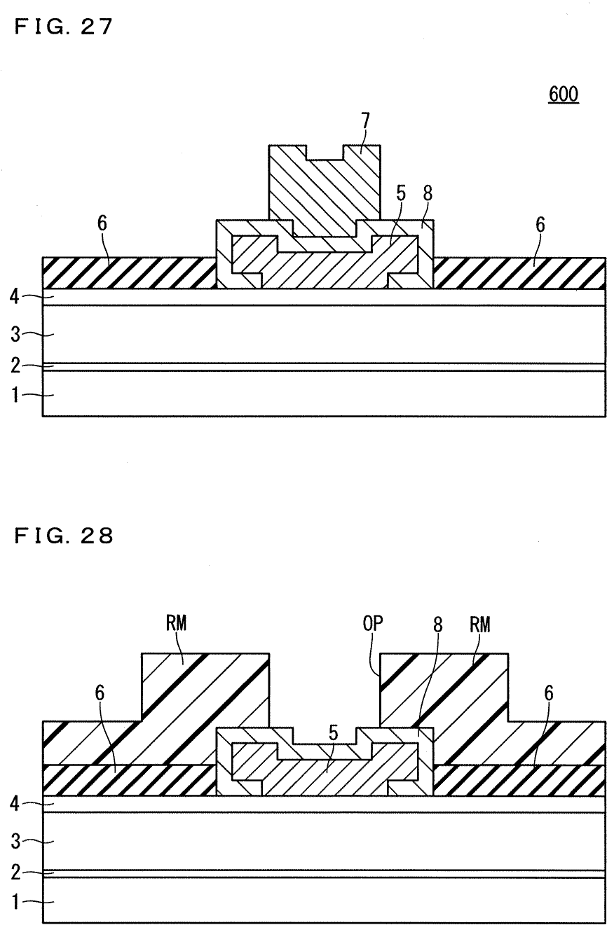

FIG. 27 is a cross-sectional view illustrating a configuration of a semiconductor device 600 according to Embodiment 6 according to the present disclosure. In FIG. 27, the same components as those of the semiconductor device 100 described with reference to FIG. 1 bear the same reference signs as those of the same components, and redundant description is omitted.

As illustrated in FIG. 27, in the semiconductor device 600, the upper surface and the side surface of the metal film 5 are covered with the composite layer 8, the composite layer 8 is provided also between the portion of the lower surface of the metal film 5 and the barrier layer 4, and the insulating film 6 of SiO₂, SiN, or the like is provided in the region over the barrier layer 4 other than the region where the composite layer 8 and the metal film 5 are formed.

The wiring layer 7 is selectively provided over the upper surface of the composite layer 8. The composite layer 8 is the silicide layer resulting from reaction of the metal film 5 and SiO₂ or the silicide layer resulting from reaction of the metal film 5 and SiN, for example, and includes the conductive portion having a lower resistance than the metal film 5. The current thus flows to the channel layer 3 via the wiring layer 7 through two types of paths, that is, a current path through which the current flows from the wiring layer 7 to the channel layer 3 via the upper composite layer 8 and the metal film 5 and the current path through which the current flows from the wiring layer 7 to the channel layer 3 via the composite layer 8, so that the effect of reducing the contact resistance is obtained.

Furthermore, the wiring layer 7 is provided to be in contact with the upper surface of the composite layer 8 to eliminate the need to provide the contact hole in the composite layer 8, so that the manufacturing step can be simplified.

### <Manufacturing Method>

A method of manufacturing the semiconductor device 600 will be described next with reference to FIG. 28 illustrating a manufacturing step. Steps before the step illustrated in FIG. 28 are the same as the steps illustrated in FIGS. 20 to 24 with reference to which the method of manufacturing the semiconductor device 500 according to Embodiment 5 has been described, and the portion where the metal film 5 and the insulating film 6 are in contact with each other is reacted by RTA and the like to form the silicide layer to be the composite layer 8, the metal film 5 is covered with the composite layer 8, and the metal film 5, the composite layer 8, and the barrier layer 4 are mutually alloyed to form the ohmic electrode. In this case, the composite layer 8 is formed also between the portion of the lower surface of the metal film 5 and the barrier layer 4.

Then, in the step illustrated in FIG. 28, the resist mask RM having the opening OP in the portion where the wiring layer 7 is desired to be formed is formed over the composite layer 8 and the insulating film 6. Then, the single layer film of Ti, Al, Ni, Au, and the like or the multilayer film of them is formed on the resist mask RM and in the opening OP by vapor deposition, and the resist mask RM is removed by lift-off to form the wiring layer 7, so that the semiconductor device 600 illustrated in FIG. 27 is obtained.

### Embodiment 7

### <Device Configuration>

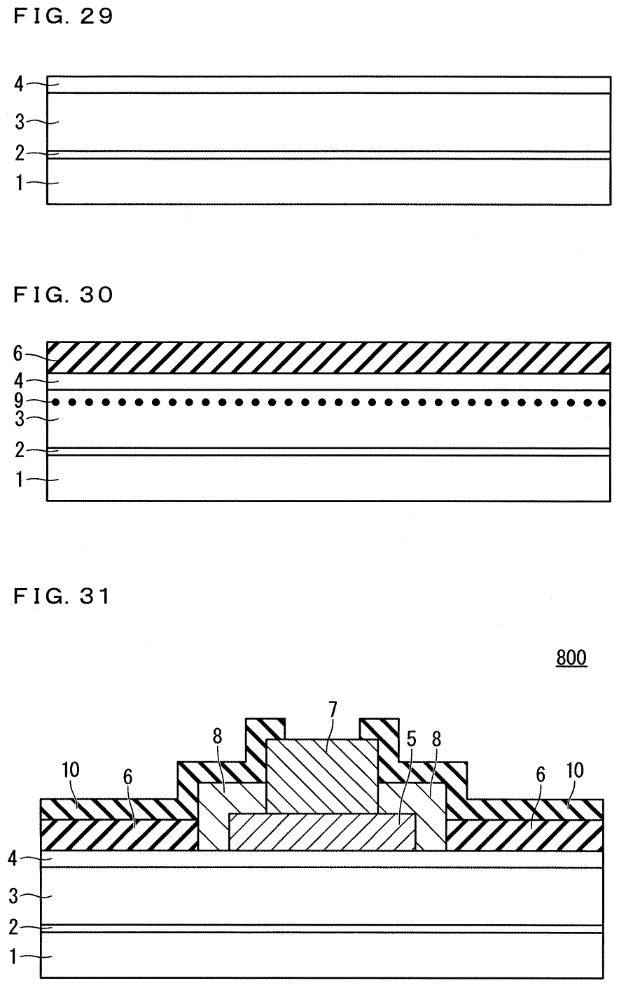

A configuration of a semiconductor device 700 according to Embodiment 7 according to the present disclosure is the same as the configuration of the semiconductor device 100 according to Embodiment 1 illustrated in FIG. 1 except that a sheet resistance due to a two-dimensional electron gas generated at an interface between the barrier layer 4 and the channel layer 3 is controlled, and the semiconductor device 700 will be described using FIGS. 29 and 30 with reference to FIG. 1.

As illustrated in FIG. 1, the semiconductor device 700 has an AlGaN/GaN heterojunction by including the channel layer 3 formed of GaN and the barrier layer 4 formed of AlGaN formed on the channel layer 3 and forming a heterojunction with the channel layer 3.

In an ohmic electrode formed over the semiconductor layers having the AlGaN/GaN heterojunction, an Al composition and a thickness of the AlGaN layer are designed so that the sheet resistance due to the two-dimensional electron gas (2DEG) generated at the interface between the barrier layer 4 and the channel layer 3 (an AlGaN/GaN interface) has a sufficiently high value, that is, a value of at least 10 kΩ/sq or more in a state where the metal film 5 and the insulating film 6 are not formed, that is, a state illustrated in FIG. 29.

For example, when the barrier layer 4 of AlGaN has an Al composition of 15% and a thickness of 7 nm, an Al composition of 20% and a thickness of 5 nm, or an Al composition of 100% and a thickness of 1 nm, the sheet resistance is 10 kΩ/sq or more.

A sheet resistance in the above-mentioned state where the barrier layer 4 is only formed on the channel layer 3 is defined as a sheet resistance unique to the barrier layer 4.

The insulating film 6 of SiO₂, for example, is deposited over the barrier layer 4 formed of the AlGaN layer designed as described above, and heat treatment is performed at a temperature of 500° C. to 900° C., so that the 2DEG having a concentration of 1×10₁₂ cm₋₂ or more can be induced at the AlGaN/GaN interface. This state is schematically shown in FIG. 30.

FIG. 30 illustrates a 2DEG 9 induced at the interface between the channel layer 3 and the barrier layer 4, and the sheet resistance is reduced by the 2DEG to be 1 kΩ/sq or less, for example.

In a semiconductor device, such as a transistor and a diode, formed of a nitride semiconductor using the 2DEG induced as described above as a carrier, heat treatment at a high temperature for the purpose of inducing the 2DEG and heat treatment at a high temperature for the purpose of forming the ohmic electrode having a low resistance described in Embodiments 1 to 6 are required, but heat treatments are not required to be performed individually and are performed simultaneously to simplify a process.

That is to say, formation of the composite layer 8 to form the ohmic electrode having a low resistance described in Embodiments 1 to 6 and heat treatment at a high temperature to induce the 2DEG are performed simultaneously to simplify the process.

The structure of the ohmic electrode according to the present disclosure becomes a more effective structure when the sheet resistance due to the 2DEG generated at the AlGaN/GaN interface has a sufficiently high value, that is, a value of at least 10 kΩ/sq or more in the state where the metal film 5 and the insulating film 6 are not formed.

### Embodiment 8

### <Device Configuration>

A configuration of a semiconductor device according to Embodiment 8 according to the present disclosure is the same as the configuration of the semiconductor device 100 according to Embodiment 1 illustrated in FIG. 1 except that the composite layer 8 includes one or more metal elements included in the barrier layer 4 and the metal film 5 along with an element forming the insulating film 6, and the semiconductor device according to the present embodiment will be described with reference to FIG. 1.

The metal elements included in the composite layer 8 can include one or more of Ga, Al, and Au. With such a configuration, the composite layer 8 includes a material forming the semiconductor device, in particular, a nitride semiconductor device, so that a semiconductor device having stable electrical characteristics with no unnecessary impurities entering into the composite layer 8 is obtained.

Herein, the barrier layer 4 can be formed of AlGaN, the metal film 5 can be formed of Al or Au, and the composite layer 8 can include at least one or more of Al and Ga as the metal elements included in the barrier layer 4 or can include at least one or more of Al and Au as the metal elements included in the metal film 5.

In other words, the composite layer 8 includes one or more of Al, Ga, and Au as the metal elements included in the barrier layer 4 and the metal film 5, so that entry of unnecessary impurities into the composite layer 8 can be suppressed.

Herein, 2 at. % or more gallium is included when the composite layer 8 includes gallium, 10 at. % or more aluminum is included when the composite layer 8 includes aluminum, and 5 at. % or more gold is included when the composite layer 8 includes gold. With such a configuration, the composite layer 8 can be formed of a material forming the semiconductor device, in particular, the nitride semiconductor device, so that complication of a manufacturing process can be suppressed.

While description has been made in Embodiment 8 by taking the composite layer 8 in the configuration of the semiconductor device 100 according to Embodiment 1 illustrated in FIG. 1 as an example, the composite layer 8 of each of the semiconductor devices 200 to 700 according to Embodiments 2 to 7 can include one or more metal elements included in the barrier layer 4 and the metal film 5.

### Embodiment 9

### <Device Configuration>

FIG. 31 is a cross-sectional view illustrating a configuration of a semiconductor device 800 according to Embodiment 9 according to the present disclosure. In FIG. 31, the same components as those of the semiconductor device 100 described with reference to FIG. 1 bear the same reference signs as those of the same components, and redundant description is omitted.

As illustrated in FIG. 31, the semiconductor device 800 includes an insulating film 10 partially covering the insulating film 6, the composite layer 8, and the wiring layer 7 in addition to the configuration of the semiconductor device 100 illustrated in FIG. 1. When the semiconductor device 800 is a transistor, the insulating film 10 functions as a gate insulating film for a gate electrode provided in an unillustrated portion. When the gate insulating film is provided separately, the insulating film 10 functions as a protective film for the gate electrode. The insulating film 10 can be formed of Al₂O₃, SiO₂, or SiN as with the insulating film 6.

As described above, also in a configuration in which the insulating film 10 is further provided over the ohmic electrode formed over the semiconductor layers having the AlGaN/GaN heterojunction, the presence of the composite layer 8 produces an effect of reducing the contact resistance, and use of the insulating film 10 as the gate insulating film or the protective film for the gate electrode can suppress any abnormality, such as deterioration, alteration, and separation of the gate insulating film or the gate electrode, enabling implementation of various semiconductor devices.

While a configuration in which the insulating film 10 is provided for the semiconductor device 100 is illustrated in FIG. 31, the insulating film 10 can be provided for a configuration of any of the semiconductor devices 200 to 700 according to Embodiments 2 to 7.

### Embodiment 10

### <Device Configuration>

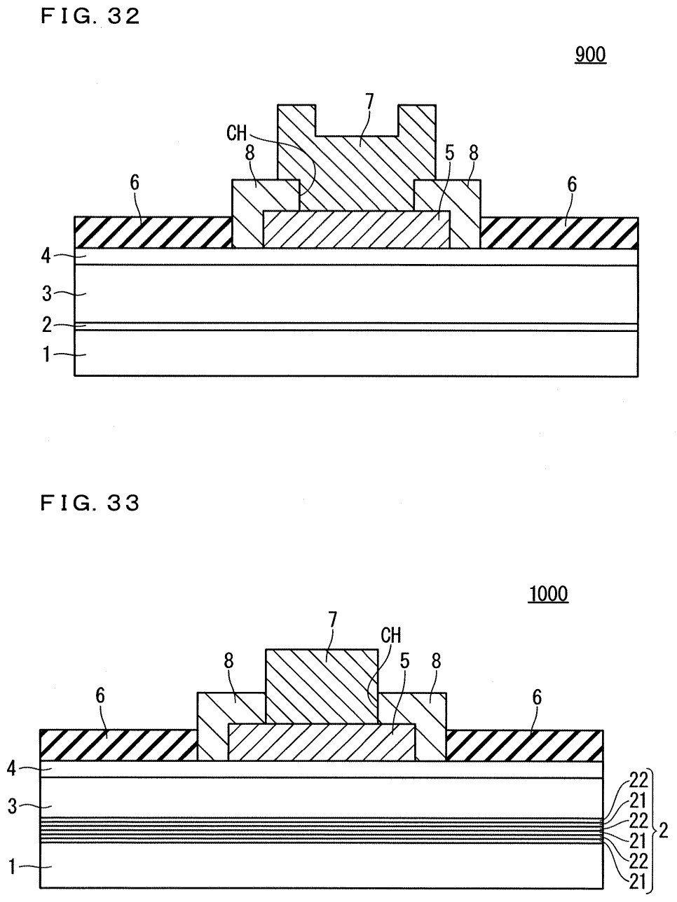

FIG. 32 is a cross-sectional view illustrating a configuration of a semiconductor device 900 according to Embodiment 10 according to the present disclosure. In FIG. 32, the same components as those of the semiconductor device 100 described with reference to FIG. 1 bear the same reference signs as those of the same components, and redundant description is omitted.

As illustrated in FIG. 32, in the semiconductor device 900, the wiring layer 7 is provided not only in the contact hole CH provided in the composite layer 8 but also to engage with a portion of a top portion of the composite layer 8. With such a configuration, the contact hole CH is completely covered with the wiring layer 7, so that formation of a gap between the contact hole CH and the wiring layer 7 can be prevented. Any abnormality, such as separation of the composite layer 8 and deterioration of the metal film 5 in the contact hole CH, can be suppressed.

### Embodiment 11

### <Device Configuration>

FIG. 33 is a cross-sectional view illustrating a configuration of a semiconductor device 1000 according to Embodiment 11 according to the present disclosure. In FIG. 33, the same components as those of the semiconductor device 100 described with reference to FIG. 1 bear the same reference signs as those of the same components, and redundant description is omitted.

As illustrated in FIG. 33, the semiconductor device 1000 has a configuration in which the buffer layer 2 includes alternating AlN layers 21 and AlGaN layers 22. Such a configuration produces an effect of suppressing deterioration of a crystal quality due to a difference in lattice constant between the semiconductor substrate 1 and the channel layer 3 formed of GaN.

### Embodiment 12

### <Device Configuration>

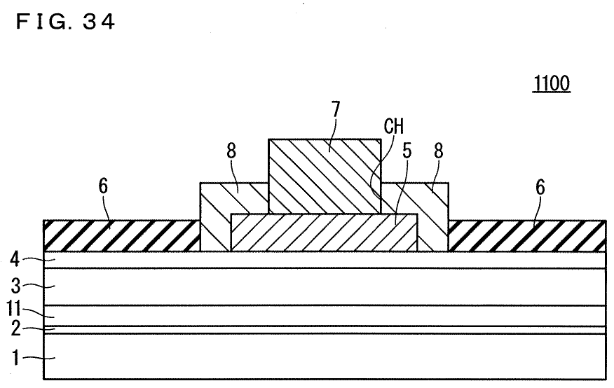

FIG. 34 is a cross-sectional view illustrating a configuration of a semiconductor device 1100 according to Embodiment 12 according to the present disclosure. In FIG. 34, the same components as those of the semiconductor device 100 described with reference to FIG. 1 bear the same reference signs as those of the same components, and redundant description is omitted.

As illustrated in FIG. 34, the semiconductor device 1100 has a configuration in which a back barrier layer 11 formed of AlGaN is formed over the buffer layer 2. By providing the back barrier layer 11 formed of AlGaN having a larger band gap than GaN of the channel layer 3, a drain leakage current can be suppressed.

### <Modifications>

While the semiconductor substrate 1 is formed of SiC, the buffer layer 2 is formed of AlN, the channel layer 3 is formed of GaN, and the barrier layer 4 is formed of AlGaN in each of the semiconductor devices 100 to 1100 according to Embodiments 1 to 12 described above, materials for them are not limited to these materials.

That is to say, the semiconductor substrate 1 can be formed of Si, sapphire, AlN, and GaN. While the buffer layer 2 is required when SiC or Si as a different material from a material for the channel layer 3 are used for the semiconductor substrate 1, the buffer layer 2 is not necessarily required when GaN, AlGaN, or InAlGaN as the same material as the material for the channel layer 3 is used for the semiconductor substrate 1.

The effect of each of the embodiments according to the present disclosure can thus be obtained when the channel layer 3 and the barrier layer 4 are formed as the semiconductor layers formed over the semiconductor substrate 1.

The buffer layer can be formed of GaN and AlGaN, and the channel layer 3 can be formed of AlGaN and InAlGaN. The barrier layer 4 can be formed of GaN, AlN, InAlGaN, and InAIN.

Materials for the insulating film 6 and the insulating film 10 are not limited to SiO₂ or SiN, and the insulating film 6 and the insulating film 10 can be formed of alumina (Al₂O₃), HfOₓ, SiON, AlON, and HfON.

A nitride semiconductor layer can be a non-doped semiconductor layer including no impurities but can include impurities, such as Si, Mg (magnesium), Fe (iron), C (carbon), and Ge (germanium), if an impurity amount is an amount not interfering with transistor operation.

While the present disclosure has been described in detail, the foregoing description is in all aspects illustrative and not restrictive. It is understood that numerous unillustrated modifications can be devised without departing from the scope of the present disclosure.

Embodiments of the present disclosure can freely be combined with each other and can be modified or omitted as appropriate within the scope of the present disclosure.

1. A semiconductor device comprising:
a semiconductor substrate;
a channel layer provided over the semiconductor substrate and formed of a first nitride semiconductor;
a barrier layer provided over the channel layer and formed of a second nitride semiconductor having a larger band gap than the first nitride semiconductor;
a metal film selectively formed above the barrier layer;
a composite layer provided to be in contact with the metal film and having at least a conductive material and an insulating material; and
an insulating film formed over the barrier layer in a region where the metal film and the composite layer are not formed, wherein
in a state where the metal film and the insulating film are not formed, a sheet resistance due to a two-dimensional electron gas generated at an interface between the channel layer and the barrier layer in a region where the barrier layer is in contact with the insulating film is 10 kΩ/sq or more.

2. The semiconductor device according to claim 1, wherein
the composite layer is provided to cover a portion of an upper surface of the metal film opposite the barrier layer and to cover a side surface of the metal film, and
a wiring layer is provided to be in contact with a region where the composite layer is not provided over the upper surface of the metal film.

3. The semiconductor device according to claim 1, wherein
the composite layer is provided to cover an upper surface of the metal film opposite the barrier layer and a side surface of the metal film, and
a wiring layer is provided to be in contact with the composite layer over the upper surface of the metal film.

4. The semiconductor device according to claim 1, wherein
the composite layer is provided to cover a portion of an upper surface of the metal film opposite the barrier layer and to cover a side surface of the metal film and a lower surface of the metal film opposite the upper surface, and
a wiring layer is provided to be in contact with a region where the composite layer is not provided over the upper surface of the metal film.

5. The semiconductor device according to claim 1, wherein
the composite layer is provided to cover an upper surface of the metal film opposite the barrier layer, a side surface of the metal film, and a lower surface of the metal film opposite the upper surface, and
a wiring layer is provided to be in contact with the composite layer over the upper surface of the metal film.

6. The semiconductor device according to claim 1, wherein
the composite layer is provided to cover a portion of an upper surface of the metal film opposite the barrier layer and to cover a side surface of the metal film and a portion of a lower surface of the metal film opposite the upper surface, and
a wiring layer is provided to be in contact with a region where the composite layer is not provided over the upper surface of the metal film.

7. The semiconductor device according to claim 1, wherein
the composite layer is provided to cover an upper surface of the metal film opposite the barrier layer, a side surface of the metal film, and a portion of a lower surface of the metal film opposite the upper surface, and
a wiring layer is provided to be in contact with the composite layer over the upper surface of the metal film.

8. (canceled)

9. The semiconductor device according to claim 1, wherein
the composite layer is a silicide layer of the metal film.

10. The semiconductor device according to claim 1, wherein
the channel layer is formed of gallium nitride, and
the barrier layer is formed of aluminum gallium nitride.

11. The semiconductor device according to claim 1, wherein
the composite layer includes one or more metal elements included in the barrier layer and the metal film along with an element forming the insulating film.

12. The semiconductor device according to claim 11, wherein
the metal elements include one or more of gallium, aluminum, and gold.

13. The semiconductor device according to claim 12, wherein
when the metal elements are gallium, 2 at. % or more gallium is included,
when the metal elements are aluminum, 10 at. % or more aluminum is included, and
when the metal elements are gold, 5 at. % or more gold is included.

14. A method of manufacturing the semiconductor device according to claim 1, the method comprising:
forming the channel layer over the semiconductor substrate;
forming the barrier layer over the channel layer;
selectively forming the metal film over the barrier layer;
forming the insulating film to cover the metal film; and
after forming the insulating film, performing heat treatment at a temperature of 500° C. or more and 900° C. or less to react a portion where the metal film and the insulating film are in contact with each other to form the composite layer.

15. A method of manufacturing the semiconductor device according to claim 1, the method comprising:
forming the channel layer over the semiconductor substrate;
forming the barrier layer over the channel layer;
forming a first insulating film over the barrier layer;
selectively forming the metal film over the first insulating film;
forming a second insulating film to cover the metal film; and
after forming the second insulating film, performing heat treatment at a temperature of 500° C. or more and 900° C. or less to react a portion where the metal film, the first insulating film, and the second insulating film are in contact with one another to form the composite layer.

16. A method of manufacturing the semiconductor device according to claim 1, the method comprising:
forming the channel layer over the semiconductor substrate;
forming the barrier layer over the channel layer;
forming a first insulating film over the barrier layer;
partially removing the first insulating film to form a contact hole extending to the barrier layer;
selectively forming the metal film over the first insulating film including the contact hole;
forming a second insulating film to cover the metal film; and
after forming the second insulating film, performing heat treatment at a temperature of 500° C. or more and 900° C. or less to react a portion where the metal film, the first insulating film, and the second insulating film are in contact with one another to form the composite layer.
